(19) United States
(12) Patent Application Publication
(10) Pub. No.: US 2012/0116731 A1
(43) Pub. Date: May 10, 2012

(54) Multidimensional relaxometry methods for consumer goods

(76) Inventor: Charles David Eads, Mason, OH (US)

(21) Appl. No.: 12/925,994

(22) Filed: Nov. 4, 2010

(51) Int. Cl. G06F 17/11; G06F 17/10; G06F 15/00; G01M 99/00; G01R 33/44

(52) U.S. Cl. 703/2; 73/865.8; 324/307; 702/127

(57) ABSTRACT

Multidimensional relaxometry methods for products and/or systems resulting from the use of such methodology, as well as processes for making, changing and/or using such products and/or systems are disclosed. Such methodologies can obviate the current shortcomings of currently available measurement methodologies and can be used to define component parameters that can be used to produce new and/or superior products and/or systems.

### COMPUTER PROGRAM LISTING APPENDIX

A computer program listing appendix on compact disc is included in the application. This computer program listing appendix contains a listing of the source code for several programs related to Multidimensional Relaxometry. These programs are written for and tested on Matlab version 2010a and are compatible with the following operating system(s): Microsoft Windows XP and later, LINUX, and Mac OS-X. These programs are also supplied on a CD-R as “m-files”, which are text files readable by a simple text editor and which can also be run by MATLAB on a Mac or PC or many other machines. An original copy, COPY 1, of a compact disc containing the following files:

rowspaceexp, which finds the response curves that best fit the row space of D, by a generalized eigenvector method implemented using SVD. Size in bytes: 2 Kbytes. Date of Creation: Oct. 11, 2010;

gem2d, which uses linear self modeling to find descriptors and the spectral matrix for a two-dimensional relaxometry data matrix. Size in bytes: 7 Kbytes. Date of Creation: Oct. 11, 2010;

gsm2d, which performs group self-modeling on a series of 2d experiments. Size in bytes: 4 Kbytes. Date of Creation: Oct. 11, 2010; and

obp2d, which does two-dimensional orthogonal basis parameterization for data in the form of T1-T2 NMR experiments (data that decay up during period E and down during period D). Size in bytes: 4 Kbytes. Date of Creation: Oct. 11, 2010;

is submitted herewith along with a duplicate copy, COPY 2, of the original compact disc. COPY 1 and COPY 2 are identical. The content of the compact discs is incorporated-by-reference into this application.

### FIELD OF THE INVENTION

This application relates to multidimensional relaxometry methods, products and/or systems resulting from the use of such methodology, as well as processes for making, changing and/or using such products and/or systems.

### BACKGROUND OF THE INVENTION

Design, formulation, testing, and production of products and/or systems often require input from analytical and physical measurements of material properties and behavior. Such measurements can be time-consuming, expensive, and may provide only limited information on the properties or behaviors of interest, either because the resulting data do not contain the desired information, or because data analysis methods are not available for extracting the information that is contained in the data. In short, Applicants recognized that the sources of the problem were that measurements do not produce data having sufficiently rich information content, and that even if the data contained the required information, that the data could not be reduced to useful parameters. Thus, there is a need for effective and efficient methodology that reduces the shortcomings and limitations of existing methods. The multidimensional relaxometry methods disclosed herein meet the aforementioned need and, in addition, can be used to define component parameters that can be used to produce improved products and/or systems.

### SUMMARY OF INVENTION

Multidimensional relaxometry, methods for producing products and/or systems resulting from the use of such methodology, as well as processes for making, changing and/or using such products and/or systems are disclosed. Such methodologies can obviate the current shortcomings of currently available measurement methodologies and can be used to define parameters that can be used to produce new and/or superior products and/or systems.

### BRIEF DESCRIPTION OF FIGURES

FIG. 1. Depicts a representative time line for a two-dimensional relaxometry experiment wherein independent variable is time and runs horizontally.

FIG. 2. Depicts a representative time line for a three-dimensional relaxometry experiment wherein, for each new dimension, a new period E and an optional new period M are introduced. The E periods are incremented independently.

FIG. 3. Depicts a time line for a two-dimensional dynamic vapor sorption/desorption experiment.

FIG. 4. Depicts the analysis of a 2D dynamic vapor sorption/desorption experiment performed using linear self modeling.

FIG. 5. Depicts the two-dimensional NMR pulse sequence used for the analysis of hydrated flour and test laundry detergent formulation materials.

FIG. 6. Depicts the results of the analysis of T1-T2 two-dimensional NMR relaxometry data acquired for flour-water mixtures.

FIG. 7. Depicts the basis functions extracted from group self-modeling of T1-T2 two-dimensional NMR relaxometry data acquired for variants of a liquid laundry formulation.

FIG. 8. Depicts a scores plot from principal components analysis of a collection of liquid laundry formulations.

### DETAILED DESCRIPTION OF THE INVENTION

### Definitions

As used herein, “multidimensional relaxometry” includes any technique or set of techniques that measure correlated descriptors of return to steady state, equilibrium and/or recovery due to a perturbation of the internal state, due to a change in external conditions, and/or due to recovery from a spontaneous fluctuation.

As used herein “product” means an economic good and/or service that encompasses “consumer goods”.

As used herein “system” means a group of one or more items, that may or may not be contiguous in space, that can be viewed as a unified whole and that may be an interacting and interdependent in the group contains two or more items.

As used herein, a process is a system that has inputs and/or out puts.

As used herein “consumer goods” includes, unless otherwise indicated, articles, baby care, beauty care, fabric & home care, family care, feminine care, health care, snack and/or beverage products or devices intended to be used or consumed in the form in which it is sold, and is not intended for subsequent commercial manufacture or modification. Such products include but are not limited to home décor, batteries, diapers, bibs, wipes; products for and/or methods relating to treating hair (human, dog, and/or cat), including bleaching, coloring, dyeing, conditioning, shampooing, styling; deodorants and antiperspirants; personal cleansing; cosmetics; skin care including application of creams, lotions, and other topically applied products for consumer use; and shaving products, products for and/or methods relating to treating fabrics, hard surfaces and any other surfaces in the area of fabric and home care, including: air care, car care, dishwashing, fabric conditioning (including softening), laundry detergency, laundry and rinse additive and/or care, hard surface cleaning and/or treatment, and other cleaning for consumer or institutional use; products and/or methods relating to bath tissue, facial tissue, paper handkerchiefs, and/or paper towels; tampons, feminine napkins; products and/or methods relating to oral care including toothpastes, tooth gels, tooth rinses, denture adhesives, tooth whitening; over-the-counter health care including cough and cold remedies, pain relievers, pet health and nutrition, and water purification; processed food products intended primarily for consumption between customary meals or as a meal accompaniment (non-limiting examples include potato chips, tortilla chips, popcorn, pretzels, corn chips, cereal bars, vegetable chips or crisps, snack mixes, party mixes, multigrain chips, snack crackers, cheese snacks, pork rinds, corn snacks, pellet snacks, extruded snacks and bagel chips); and coffee and cleaning and/or treatment compositions

As used herein, the term “cleaning and/or treatment composition” includes, unless otherwise indicated, tablet, granular or powder-form all-purpose or “heavy-duty” washing agents, especially cleaning detergents; liquid, gel or paste-form all-purpose washing agents, especially the so-called heavy-duty liquid types; liquid fine-fabric detergents; hand dishwashing agents or light duty dishwashing agents, especially those of the high-foaming type; machine dishwashing agents, including the various tablet, granular, liquid and rinse-aid types for household and institutional use; liquid cleaning and disinfecting agents, including antibacterial hand-wash types, cleaning bars, mouthwashes, denture cleaners, car or carpet shampoos, bathroom cleaners; hair shampoos and hair-rinses; shower gels and foam baths and metal cleaners; as well as cleaning auxiliaries such as bleach additives and “stain-stick” or pre-treat types.

As used herein, the articles “a”, “an”, and “the” when used in a claim, are understood to mean one or more of what is claimed or described.

Unless otherwise noted, all component or composition levels are in reference to the active level of that component or composition, and are exclusive of impurities, for example, residual solvents or by-products, which may be present in commercially available sources.

All percentages and ratios are calculated by weight unless otherwise indicated. All percentages and ratios are calculated based on the total composition unless otherwise indicated.

It should be understood that every maximum numerical limitation given throughout this specification includes every lower numerical limitation, as if such lower numerical limitations were expressly written herein. Every minimum numerical limitation given throughout this specification will include every higher numerical limitation, as if such higher numerical limitations were expressly written herein. Every numerical range given throughout this specification will include every narrower numerical range that falls within such broader numerical range, as if such narrower numerical ranges were all expressly written herein.

### Overview of Multidimensional Relaxometry

Applicants teach an analytical protocol to measure one or more sample attributes as a function of an independent variable, such as time, as the system approaches steady-state from a non steady-state. For all but the simplest systems, the approach to equilibrium can follow a complex kinetic scheme. Details of the measured relaxation response provide information on the kinetic scheme and therefore reflect the composition, structure, and dynamics of the system. The specific information contained in the relaxation response may be determined by the sample, the attribute measured, the measuring device, the distance from steady state, the nature of the deviation from steady state, sample history, the final conditions, etc.

Because relaxation responses are information rich, their measurement is useful for designing and improving consumer products. Relaxation responses can be used to discover causal and empirical correlations among relaxation parameters and important properties. Industrial systems and their corresponding relaxation response curves are usually complicated, so evaluation and parameterization of the response curves is difficult and challenging. Thus Applicants recognized the need to devise experimental protocols that encode the desired information in the relaxation responses, and data analysis methods that extract the desired information.

Applicants teach an approach for obtaining and extracting the rich information contained in the approach to steady-state. Such approach is two-dimensional relaxometry, or by extension, multidimensional relaxometry. Multidimensional relaxometry involves independent variables that may be at least two periods, that may be time periods, during which the relaxation behavior is measured. If the experiment and data analysis are performed properly, it is possible to correlate the behavior of the signal sources in the different periods, resulting in multidimensional descriptions of the sample under study. There are numerous advantages to multidimensional relaxometry compared to the one-dimensional case. These advantages are due to the additional information content of multidimensional data sets. Among these advantages are separation, correlation, and exchange. With separation, complicated response curves can be more easily resolved into individual components because they are spread and displayed in two or more dimensions, where there is less chance of overlap among the signals. By establishing correlations of behavior under different prevailing conditions or initial states, the approach gives additional and often vital information on each signal source that can be used for assignments, mechanistic insight, etc. Experiments that provide information about exchange enable interactions or communication or influence among components or signal sources to be discerned. This often has important mechanistic and structural implications.

Applicants recognized the principles that result in non-NMR relaxometry, and multidimensional relaxometry as applied to consumer products using NMR or any other techniques. 2D (nD) NMR and related 2D spectroscopic methods can be viewed as specific examples of a heretofore unrecognized and much broader class of experimental strategies. So far, two-dimensional experiments have involved monitoring the emission or induction of electromagnetic signals where the entities responsible for the emission and/or induction are directly involved in the process of relaxation towards equilibrium or steady state. Correlation information emerges from these experiments because the emitted and/or induced signals have characteristic time dependences in each of two dimensions, and because the state at the end of one time period influences the state at the beginning of a subsequent time period. From the broader perspective claimed here, one monitors the approach of a system to equilibrium or steady state, though in this broader case the signal does not necessarily involve entities that emit or induce electromagnetic signals. Further, the sources of the signals are not necessarily directly involved in the relaxation process. Thus, in our approach, we include detection methods that probe the approach to equilibrium or steady state by monitoring changes in any convenient properties of the system or by measuring the changing response of the system to an applied probe, where the properties and/or probe are not necessarily electromagnetic in nature nor necessarily directly involved in the relaxation process.

Here, we teach how multidimensional relaxometry can be used to develop and test consumer products, and we define the principles that allow extension of multidimensional relaxometry to a vast range of analytical or physical measurement techniques. Applicants also introduce new processing methods that allow extraction of the information inherent in multidimensional relaxometry data. The information is extracted in forms useful for designing and improving consumer products.

### Implementation

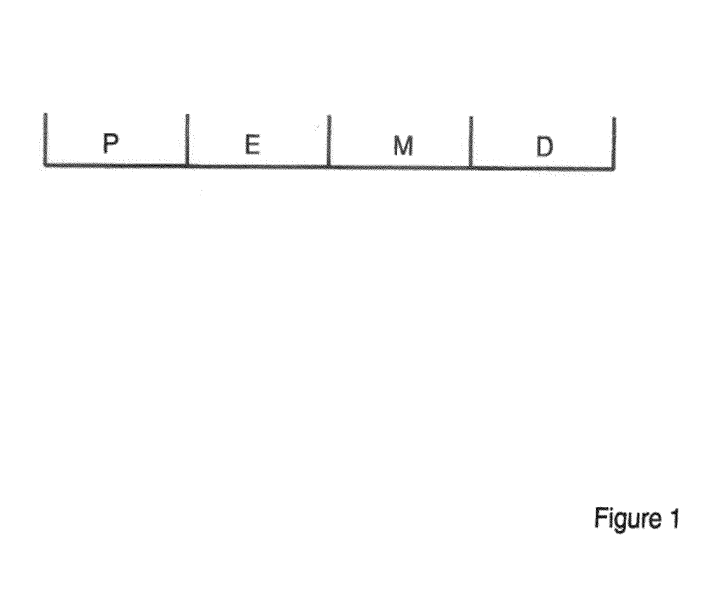

For a simple implementation of two-dimensional relaxometry, one divides an experimental time line into periods that we label P, E, M, and D, and which we might call preparation, evolution, mixing, and detection. FIG. 1 gives a diagram illustrating this two-dimensional protocol. The protocol is repeated a number of times, in which some parameter associated with the E period, usually but not necessarily time, is incremented systematically. In every time period, the system evolves according to a process or processes. Those processes will be influenced externally by the prevailing conditions, or internally by manipulating the state of the system.

The purpose of period P is to reproducibly create a starting condition that will be out of steady state or equilibrium at the start of period E, and hence will evolve towards steady state or equilibrium during period E. The purpose of period E is to allow the system to approach steady state or equilibrium to a degree and by a pathway that depends on the prevailing conditions, the starting internal state of the system, and the independent variable whose value is incremented between repetitions. In addition to being the period during which the signal is detected, the purpose of period D is to allow the system to approach steady state or equilibrium under prevailing conditions, or with respect to an internal state, wherein the prevailing conditions and/or starting internal state differ from those characterizing period E. The purpose of the optional period M is to allow or cause a signal to change its state or pathway towards steady state or equilibrium. For example, it may involve a simple delay in which material or energy or information moves from one environment to another, or it may involve exposing the sample to prevailing conditions that differ from those employed during the E and D periods, or it may involve a perturbation to the internal state of the system. Prevailing conditions and internal states are not typically altered systematically during period M.

An important aspect of designing and performing two-dimensional relaxometry with this implementation is that some aspect or aspects of the state or signal or condition at the end of period E influences the starting state or signal or condition at the beginning of period D in a manner that is reflected in the detected signal. Signals that behave this way can be processed to discover correlations between behavior in the evolution and detection periods. An appropriate data analysis protocol must be used to establish the correlations.

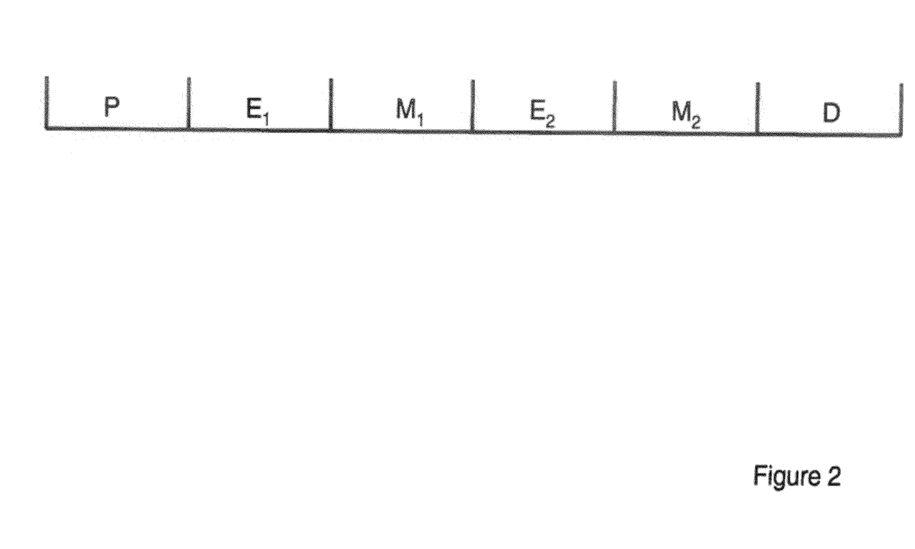

FIG. 2 shows that the two-dimensional scheme can be easily generalized to three or more dimensions. For each added dimension, one inserts an additional E and M pair, where as before the M period is optional. Thus, the scheme for an n-dimensional experiment is P−(Eᵢ−Mᵢ−)ᵢD, where the term in parenthesis is executed for all n−1 pairs of E and (optional) M periods, where n is the number of dimensions.

In the case of multidimensional NMR, spin ensembles precess during the evolution and detection periods at characteristic frequencies, inducing signals that are recorded. Algorithms such as Fourier transformation, linear prediction, or filter diagonalization can be used to convert the time-domain signals into multidimensional frequency domain maps that exhibit informative correlations. In the multidimensional relaxometry experiments described here, it is recognized that the signals do not need to originate as emitted or induced electromagnetic signals. It is also recognized that the signals do not need to conform to sinusoidal behavior or even to any pre-conceived functional form at all, so long as the state at the end of one time period influences the starting state in the subsequent period.

### Analysis of Multidimensional Relaxometry for First Order Processes

While not bound by theory, it is informative to discuss expected multidimensional relaxometry behavior for the case involving first-order relaxation processes. First-order relaxation occurs broadly in chemical kinetic schemes, NMR relaxation, and elsewhere. The sample is considered to contain or exhibit one or more signal sources. A signal source is an aspect of the sample that can be characterized by a numerical value, and that value is considered the detected signal. For example, in NMR relaxometry, the signal sources might comprise the groups of nuclei having similar relaxation rates and/or chemical shifts and/or belonging to specific molecular species. In chemical kinetics, the signal sources may be chromophores, weights of materials, or any physical measure of the deviations of the system from equilibrium or steady-state. The signal sources may be, but do not need to be, physically contiguous. During periods E and D, each signal source evolves towards steady state or equilibrium as a function of its starting state, the prevailing conditions, and the state of other signal sources which might influence it.

We will first describe the one-dimensional case to establish methods and nomenclature for familiar circumstances, then we will extend the discussion to the two-dimensional case, noting that extension to higher dimensions is straightforward. We will also use explicit matrix language in order to simplify the notation. Vectors are symbolized using lower-case bold letters, as in v, and are assumed to be arranged as columns. Matrices are symbolized by upper-case bold letters, as in M. The transpose operation is designated using a superscript T, as in M^{T}. The inverse operation is designated using a superscript −1, as in M⁻¹. Pseudoinverses are denoted using a superscript †, as in M^{†}. We use the special symbol 1 to denote a column vector having every element equal to 1. Conversion to continuum language, and generalization to non-linear or more complex systems, can be achieved by straightforward methods well known to those skilled in the art.

In the one-dimensional case, the differential equation for a relaxation response signal is assumed to be

$$\frac{d}{d t} m = Rm \qquad ( 0.1 )$$

where m is a column vector whose elements describe the state of the signal sources and can be related to amount of signal originating from each signal source. R is the relaxation or kinetic propagation matrix. R will usually be real for exponential response functions, but may be complex for sinusoidal or more complicated response functions. The diagonal elements R_{n,n} are typically combinations of relaxation rate constants or kinetic rate constants, and will usually have a negative sign. The off diagonal elements σ_{m,n} characterize processes that can cause signal sources to influence one another, for example by diffusion, cross relaxation, chemical exchange, or other processes whereby one signal source can influence another signal source. The relaxation matrix is not necessarily symmetric. For a system having four signal sources, R would explicitly look like this:

$$R = [ \begin{matrix}{R}_{1 , 1} & {σ}_{1 , 2} & {σ}_{1 , 3} & {σ}_{1 , 4} \\ {σ}_{2 , 1} & {R}_{2 , 2} & {σ}_{2 , 3} & {σ}_{2 , 4} \\ {σ}_{3 , 1} & {σ}_{3 , 2} & {R}_{3 , 3} & {σ}_{3 , 4} \\ {σ}_{4 , 1} & {σ}_{4 , 2} & {σ}_{4 , 3} & {R}_{4 , 4}\end{matrix} ] \qquad ( 0.2 )$$

Given a time-independent R and the initial state vector m₀, we can solve (0.1) by diagonalizing the relaxation matrix.

m(t)=e^{Rt}m₀=Ve^{Λt}V⁻¹m₀ (0.3)

where

R=VΛV⁻¹ (0.4)

V is a matrix of eigenvectors, and Λ is a diagonal matrix of eigenvalues. As is well known, the simplification from this procedure arises, in part, because the exponentiation of a diagonal matrix as in e^{Λt} is achieved easily by exponentiating the diagonal elements. We will assume that the data are sums of all the signals from the signal sources. We achieve the summation by introducing a scalar product involving the vector 1. Thus, a data point at time t can be expressed

d(t)=1^{T}e^{Rt}m₀=1^{T}Ve^{Λt}V⁻¹m₀=\tilde{1}^{T}e^{Λt}\tilde{m}₀ (0.5)

According to equation (0.5), for the broad class of samples obeying first-order relaxation kinetics, the response curve would be a multi-exponential decay (a sum of single exponential decays), even if the kinetic propagation matrix contains off-diagonal elements. The intensities of those decays, however, will not be directly given by the amount of magnetization in the original signal sources because the non-diagonal relaxation matrix effectively mixes the source intensities into relaxation modes.

For data sampled discretely at regular intervals, it is convenient to express the k^{th} time point in (0.5) as

dₖ=\tilde{1}^{T}Z^{k}\tilde{m}₀ (0.6)

where k is an integer, and the diagonal matrix Z is given by

Z=e^{ΛΔt} (0.7)

and Δt is the sampling increment.

Because the matrix Z is diagonal, it commutes with other diagonal matrices. One may therefore use diagonal matrices Δ and Δ⁻¹ (whose product is the unit identity matrix I) to adjust the values of individual elements of \tilde{1} and the corresponding elements of \tilde{m}₀. In particular, if we find a Δ such that \tilde{1}^{T}Δ=1^{T}, we may write

dₖ=\tilde{1}^{T}Z^{k}\tilde{m}₀=\tilde{1}^{T}ΔΔ⁻¹Z^{k}\tilde{m}₀=\tilde{1}^{T}ΔZ^{k}Δ⁻¹\tilde{m}₀ (0.8)

or

dₖ=1^{T}Z^{k}b (0.9)

This allows us to express the data points in a form in which all the intensity information for the relaxation modes is contained in the right column vector b.

Two-Dimensional Case For 2D relaxometry the analysis is similar, except that for every change in internal state or external conditions, one must operate on the state vector m to account for that change. We label the state vector according to FIG. 1. At the end of period E we have

m_{E}(t_{E})=e^{R}^{_{E}}^{t}^{_{E}}m₀ (0.10)

where R_{E} is the relaxation matrix appropriate to period E, and t_{E} is the duration of period E. If the prevailing conditions are changed in transitioning to the next period, it is possible that the signal sources may also change, for example, by becoming farther or nearer to equilibrium with respect to the prevailing conditions. Such a change will introduce an additive component to the distance from equilibrium. The consequence of such a shift will be the introduction of “axial signals”, which are signals that arise during the experiment but which do not depend on the duration of the prior period. This will be demonstrated in the worked example, though in the following it is assumed that precautions are taken to eliminate the axial signals through data processing or experimental design.

After the optional M period, the system will become

m_{M}=e^{R}^{_{M}}^{t}^{ₘ}e^{R}^{_{E}}^{t}^{_{E}}m₀ (0.11)

where R_{M} is the relaxation matrix applicable during period M, and τₘ is the duration of period M. Switching external conditions for the detection period may again change the signal sources, making an additional contribution to the axial signals. Again, to simplify the present discussion, we assume precautions are taken to eliminate these signals.

The signal state vector detected during period D will then be described by

m_{D}(t_{E},t_{D})=e^{R}^{_{D}}^{t}^{_{D}}e^{R}^{_{M}}^{τ}^{ₘ}e^{R}^{_{E}}^{t}^{_{E}}m₀ (0.12)

where R_{D} is the relaxation matrix applicable during period D, and m_{D} (t_{E},t_{D}) lists the signals from each signal source as a function of the independent parameters t_{E} and t_{E}, for the evolution and detection periods, respectively.

The measured signal for independent variable values (t_{E},t_{D}) will be given by

d(t_{E},t_{D})=1^{T}e^{R}^{_{D}}^{t}^{_{D}}e^{R}^{_{M}}^{τ}^{ₘ}e^{R}^{_{E}}^{t}^{_{E}}m₀ (0.13)

This can be expanded by diagonalization of the relaxation matrices to give

d(t_{E},t_{D})=(1^{T}V_{D})e^{Λ}^{_{D}}^{t}^{_{D}}(V_{D}⁻¹V_{M}e^{Λ}^{_{M}}^{t}^{ₘ}V_{M}⁻¹V_{E})e^{Λ}^{_{E}}^{t}^{_{E}}(V_{E}⁻¹m₀)=\tilde{1}^{T}e^{Λ}^{_{D}}^{t}^{_{D}}\tilde{V}_{M}e^{Λ}^{_{E}}^{t}^{_{E}}m₀ (0.14)

where

\tilde{V}_{M}=V_{D}⁻¹V_{M}e^{Λ}^{_{M}}^{τ}^{ₘ}V_{M}⁻¹V_{E} (0.15)

Assuming that the data are sampled discretely and at regular intervals to yield a two dimensional time series arranged in a matrix, the data points are given by

d_{j,k}=\tilde{1}^{T}e^{Λ}^{_{D}}^{jτ}^{_{D}}\tilde{V}ₘe^{Λ}^{_{E}}^{kτ}^{_{E}}\tilde{m}₀ (0.16)

or

d_{j,k}=\tilde{1}^{T}Z_{D}^{j}\tilde{V}ₘZ_{E}^{k}\tilde{m}₀ (0.17)

where the matrices Z_{E} and Z_{D} are diagonal, the elements at position n, n have the form Z_{E,nn}=e^{λ}^{_{E,n}}^{τ}^{_{E}} and z_{D,nn}=e^{λ}^{_{D,n}}^{τ}^{_{D}}, and j and k are integers. If period M is missing and/or if the changes from period to period do not influence the state, then the appropriate matrices in the expressions above are replaced with the identity matrix. If the mixing period is absent (e^{R}^{_{M}}^{τ}^{ₘ}=I), the matrix \tilde{V}_{M} will still be important, and almost always non-diagonal, because it will still involve the product V_{D}⁻¹V_{E}.

As with the 1-dimensional case, because the matrices Z_{E} and Z_{D} are diagonal, it is possible to manipulate intensities with complementary diagonal matrices I=ΔΔ⁻¹ to get

d_{j,k}=\tilde{1}^{T}Z_{D}^{j}\tilde{V}_{M}Z_{E}^{k}\tilde{m}₀=\tilde{1}^{T}Δ_{D}Z_{D}^{j}Δ_{D}⁻¹\tilde{V}_{M}Δ_{E}Z_{E}^{k}Δ_{E}⁻¹\tilde{m}₀ (0.18)

or

d_{j,k}=1^{T}Z_{D}^{j}SZ_{E}^{k}1 (0.19)

We will adopt this convention so that the left row and right column vectors have all ones in them, and so that all of the two-dimensional relaxation mode intensity is ascribed to the matrix S, hereafter called the “spectral matrix”.

Note that, although the above discussion frames the problem assuming that time is the independent variable, the parameter to which the variable t or the indices j, k, . . . refer to are not necessarily time, but could be any independent variable that is incremented during the experiment.

### Data Analysis Methods

Two-dimensional relaxometry data are represented as a data matrix, D. Hereafter we adopt the convention that the rows contain the response curves collected during period D, where each row represents a different value of the parameter varied during period E. An important property of two-dimensional relaxometry is that we may also adopt a view of D in which the columns contain the response curves collected during period E, where each column represents a different value of the parameter varied during period D.

Many methods for analyzing two-dimensional relaxometry data can be envisioned or are already available. Without being limited to the methods described below, this section describes methods that treat the data according to expressions of the general form

D=A_{E}^{T}SA_{D} (0.20)

where combinations of the rows of A_{D} can be used or combined to model the response curves that comprise the rows of D, the columns of A_{E}^{T} can be used or combined to model components of the response curves that comprise the columns of D, and the matrix S links and combines these components to reproduce the data matrix. One can envision each row of A_{E}^{T}S as giving the amounts of each row of A_{D} to combine to give the corresponding row of D. Simultaneously, each column of SA_{D} can be viewed as giving the amounts of the columns of A_{E}^{T} that must be combined to give the corresponding column of D. There are many methods to assemble or generate the decomposition indicated in equation (0.20), and methods used will influence the manner in which A_{D}, A_{E}^{T}, and S are used and/or interpreted.

The method chosen depends on the aim of the analysis and the nature of the data. In linear self modeling, one uses linear algebra to discover A_{D}, A_{E}^{T}, and S, while at the same time generating diagonal matrices Z_{D} and Z_{E}. These can be related to the relaxation matrices as in equation (0.19) if one assumes a linear system. Advantages of linear self-modeling include that it provides a representation of the data that is unique, model-independent, and parsimonious. In orthogonal basis parameterization, the aim is to construct A_{D} and A_{E}^{T} using a small number of judiciously chosen orthogonal basis functions, and then to parameterize the data in terms of this basis. The advantages of orthogonal basis parameterization include a direct sample-to-sample correspondence in the parameters, and ease of use of the resulting parameterization in automated decision making using, for example, multivariate statistics. In group self modeling, collections of two-dimensional data are used to find a small number of basis curves that can be assembled into matrices A_{D} and A_{E}^{T} which can then be used to model any two-dimensional data set in the collection or in related data sets. Each data set is then distinguished by having a different S matrix. Group self-modeling is useful for building models of classes of samples without needing to make any assumptions about the response functions. In the inverse problem approach, the aim is to view S as a joint distribution over kernel matrices, requiring that kernels be assumed and explicitly placed in A_{D} and A_{E}^{T}. The inverse problem approach is widely used, though not in this work.

Linear Self Modeling The goal of linear self-modeling of relaxometry data is to find matrix methods that allow determination of the (possibly complex) descriptors of each signal component in each dimension. For two-dimensional data, the approach involves a pair of tri-linear matrix factorizations that do not appeal to any externally supplied basis functions. Though not essential to the method, if one makes the often-applicable assumption that the data can be described as sums of (possibly complex) exponential functions, this self-modeling method can be interpreted in terms of the parameters describing the component exponential functions. A key advantage of linear self-modeling is that, once the numbers of relaxation modes in each dimension are selected, then the solution is unique. Here, the term unique means that, aside from trivial issues of scaling and of the order in which the component curves are listed, no other solution exists. This is in contrast to bilinear factorizations, which are well known to be subject to rotational ambiguity.

While not limiting data interpretation to any specific model, to motivate the discussion we can view the data points as conforming to equation (0.19). It is convenient to arrange the data into sub-matrices which we label with two subscripts, as in D_{M,N}. Here, the first index refers to the offset in the E period, while the second index refers to the offset in the D period. For example, we can have

$$\begin{matrix}{D}_{0 , 0} = [ \begin{matrix}{d}_{0 , 0} & {d}_{0 , 1} & {d}_{0 , 2} & … \\ {d}_{1 , 0} & {d}_{1 , 1} & {d}_{1 , 2} & … \\ {d}_{2 , 0} & {d}_{2 , 1} & {d}_{2 , 2} & … \\ ⋮ & ⋮ & ⋮ & ⋱\end{matrix} ] & ( 0.21 ) \\ {D}_{0 , 1} = [ \begin{matrix}{d}_{0 , 1} & {d}_{0 , 2} & {d}_{0 , 3} & … \\ {d}_{1 , 1} & {d}_{1 , 2} & {d}_{1 , 3} & … \\ {d}_{2 , 1} & {d}_{2 , 2} & {d}_{2 , 3} & … \\ ⋮ & ⋮ & ⋮ & ⋱\end{matrix} ] & ( 0.22 ) \\ {D}_{1 , 0} = [ \begin{matrix}{d}_{1 , 0} & {d}_{1 , 1} & {d}_{1 , 2} & … \\ {d}_{2 , 0} & {d}_{2 , 1} & {d}_{2 , 2} & … \\ {d}_{3 , 0} & {d}_{3 , 1} & {d}_{3 , 2} & … \\ ⋮ & ⋮ & ⋮ & ⋱\end{matrix} ] & ( 0.23 )\end{matrix}$$

(As a mnemonic, the subscripts in the names of the matrices correspond to the subscripts of the upper left element.) These matrices can be, but are not necessarily, square. It follows from equation (0.19) that these data matrices can be described using the equation

D_{M,N}=A_{E,L}^{T}Z_{E}^{M}S_{L}Z_{D}^{N}A_{D,L} (0.24)

where the k^{th} column of A_{E,L} is generated with the expression Z_{E}^{k}1, the j^{th} column of A_{D,L} is generated with the expression Z_{D}^{j}1, and S_{L} is the spectral matrix resulting from linear self modeling.

We seek to use the matrices D_{M,N} to determine Z_{E}, Z_{D}, and S_{L}. The following describes one approach that achieves this. We begin by solving for Z_{D} using D_{0,0} and D_{0,1} as follows. According to (0.24), we may write

D_{0,0}=A_{E,L}^{T}S_{L}A_{D,L} (0.25)

D_{0,1}=A_{E,L}^{T}S_{L}Z_{D}A_{D,L} (0.26)

Any bilinear factorization of D_{0,0} must be of the form

D_{0,0}=P_{L}P_{R}=(A_{E,L}^{T}S_{L}^{1-α}Q⁻¹)(QS_{L}^{α}A_{D,L}) (0.27)

where Q is an invertible matrix, α is a number that lets us arbitrarily factor S_{L},

P_{L}=A_{D,L}^{T}S_{L}^{1-α}Q⁻¹ (0.28)

and

P_{R}=QS_{L}^{α}A_{D,L} (0.29)

The product QS_{L}^{α} is responsible for the well-known “rotational” ambiguity that arises in bi-linear decompositions common to chemometrics and other multivariate analysis methods. It will be demonstrated shortly that the precise form of the invertible matrix Q and the manner in which the parts of S_{L} are attributed to the left and right matrices via the parameter α are not important so long as P_{R} and P_{L} span the row space and the column space of D_{0,0}, respectively.

To obtain, via (0.26), the unique diagonal matrix Z_{D} using pseudo-inverses of P_{R} and P_{L}, we next solve for the intermediate result

Z_{P}=P_{L}^{†}D_{0,1}P_{R}^{†}=(QS_{L}^{α})Z_{D}(S_{L}^{-α}Q⁻¹) (0.30)

Diagonalization of Z_{P} then gives a unique (except for row order) solution Z_{D} and QS_{L}^{α}. The latter can be used with P_{R} via equation (0.29) to obtain A_{D,L}. Thus, we now have unique matrices for Z_{D} and A_{D,L}.

By an analogous method, D_{0,0} and D_{1,0} can be used to find A_{E,L} and Z_{E}. Finally, Z_{E} and Z_{D} can be used with any D_{M,N} to find S_{L}.

It is worthwhile discussing the uniqueness of the decomposition we have achieved, and its intrinsic independence of any model. Consider the decomposition of D_{0,1} according to equation (0.26) by this method.

D_{0,1}=(A_{E,L}^{T}S_{L})(Z_{D})(A_{D,L}) (0.31)

Between the first and second term in parenthesis, we can insert the product T_{L}⁻¹T_{L} for any invertible matrix T_{L}, without changing the matrix D_{0,1}. Similarly, we can insert the product T_{R}⁻¹T_{R} between the second and third terms without changing the matrix D_{0,1}. Thus, equation (0.31) becomes

D_{0,1}=(A_{E,L}^{T}S_{L}T_{L}⁻¹)(T_{L}Z_{D}T_{R}⁻¹)(T_{R}A_{D,L}) (0.32)

We have performed our decomposition, however, to force the central term to be diagonal. T_{L} and T_{R} are thus the sources of ambiguity in this decomposition. Since we require that the central matrix is diagonal, only matrices that preserve diagonality in the expression T_{L}Z_{D}T_{R}⁻¹ are allowed. Such matrices include those that accomplish scaling and row permutations, but there can be no mixing of response curves. In this sense, each of our tri-linear decompositions is unique, so that our final decomposition is also unique. Note also that the decomposition proposed here will work for any response function as long as it can be modeled by Fourier series. In most cases, compared to Fourier modeling, we expect that many fewer components will be needed for signals that possess exponential-like behavior, and for truly exponential behavior, the analysis will be interpretable in terms of relaxation rates and relaxation mode intensities.

### Orthogonal Basis Parameterization

Frequently we wish to capture the information contained in a relaxometry data set using a small set of parameters, and we want to be able to directly compare these parameters among sets of spectra. This would be useful, for example, in statistical learning and statistical decision-making applications. Though it is desirable that changes in the resulting parameters be linked to changes in the properties of the sample used to generate the data, a direct physical interpretation of the parameters may not be necessary. The important considerations here are that the parameters capture the information necessary for making decisions, that they summarize that information in a concise and actionable way, and that there is a direct correspondence of parameters among samples.

If the goal is to describe the data using a small number of parameters, any basis set that spans the function space relevant to the data may be used. Thus, a parsimonious parameterization of multi-exponential curves can be achieved by expressing the curves as linear combinations of orthogonal basis functions, where said basis functions span the space of exponential curves expected in the data. The parameterization is comprised of the coefficients of those curves. Exponential behavior is particularly well suited to this approach because exponential curves tend to be linearly dependent, meaning that they can be precisely represented using only a small basis.

For two-dimensional data sets, the data matrices can be expressed in the form

D=A_{E,B}^{T}S_{B}A_{D,B} (0.33)

where A_{E,B} and A_{D,B} are orthonormal basis sets for the two dimensions. The parameterization of the data matrix is then formally given by

S_{B}=(A_{E,B}^{T})^{†}DA_{D,B}^{†} (0.34)

where the small table of parameters in S_{B} contains all the information inherent in the two dimensional data set. In practice, methods not involving direct calculation of the pseudo-inverse can be used to solve (0.33) for S_{B}.

It remains to describe ways to generate the orthogonal basis vectors. There are many possible approaches, and as an example we describe the use of Gram-Schmidt orthogonalization of a small set of widely spaced exponential curves.

Since the rank of exponential kernel matrices is low, one does not need to generate a large number of incremented response curves to create a data set that spans the space of the data set. Rather, one can use a small number (˜10 over three orders of magnitude) of widely spaced exponential decay curves. One can perform Gram-Schmidt orthogonalization algebraically, or one can use a numerical algorithm such as QR decomposition, which implements Gram-Schmidt orthogonalization in a numerically stable way. The resulting orthonormal curves can be used as a basis set for parameterizing the data.

### Group Self Modeling

It is not always possible or desirable to begin with knowledge of the form and/or the range of the response functions inherent in the data. In this case, it may be preferable to use some or all of the experimental response curves themselves as a training set to generate orthonormal basis sets A_{E,G} and A_{D,G}. By collecting response curves into a matrix, it is possible to find a small orthogonal set that spans the space by methods such as singular value decomposition to generate small basis sets for the row and column spaces. Using this basis set, S_{G} matrices can be determined by solving (0.20). In addition to not needing to know the form of the response curves, additional benefits arise from this approach. For example, in some cases it may be found that the basis set fits data in the training collection well, but is incapable of reproducing a response curve that was not part of the training set. This will indicate the presence of a novel behavior. Observations such as this are frequently very useful.

Method of Designing, Making, Changing and/or Using a Product and/or System

In one aspect, a method of designing, making, changing and/or using a product and/or system comprising:
a) extracting information by
   i) establishing the initial state of a product and/or system, said initial state being a non-equilibrium, non-steady state;
   ii) allowing the product and/or system to progress towards a steady state, versus an independent variable;
   iii) optionally, introducing a period wherein said progress towards said steady state is altered by establishing a discontinuity in the prevailing conditions and/or internal state of said product and/or system without losing the desired information about the state of the product and/or system when said discontinuity is established;
   iv) introducing a period wherein said progress towards said steady state is altered by establishing a discontinuity in the prevailing conditions and/or internal state of said product and/or system without losing the desired information about the state of the product and/or system when said discontinuity is established and monitoring said product and/or system's progress towards steady-state using a device that provides the results in a machine readable form, in one aspect, said device comprises a computer,
   v) repeating (i)-(iv) one or more times while altering the value of said independent variable.
b) using said information to design, make, change and/or use a product and/or system, in one aspect, said use comprises using a computer to further transform said information into a form that can be more efficiently used,
is disclosed

In one aspect of said method at least one of said steady states is an equilibrium state.

In any aforementioned aspect of said method, said method may comprise one or more additional sets of steps ii) and iii) said additional set of steps ii) and iii) occurring after the initial set of steps ii) and iii); wherein each additional set of steps ii) and iii) has a different independent variable, prevailing conditions and/or internal state from the immediately preceding set of steps ii) and iii).

In any aforementioned aspect of said method, said method:
a) the method may be performed using an analytical or physical measurement tool capable of recording progress towards steady state; and/or
b) the method may be performed virtually by means of a computer simulation and progress towards steady state is a calculated function of the computed results.

In any aforementioned aspect of said method, said method any progress towards steady state may be monitored using an NMR and/or the steady may be an equilibrium state that may comprise controlled temperature and relative humidity, and progress towards steady state may be monitored using gravimetry.

In any aforementioned aspect of said method:
a) the prevailing conditions of said product and/or system may be defined by controlling or setting:
   i) a thermodynamic and/or structural parameter, in one aspect, said thermodynamic and/or structural parameter may be selected from:
      (1) temperature
      (2) pressure
      (3) volume and/or
      (4) container shape
   ii) the applied fields and/or the spatial distribution of said fields, said fields being either time dependent or time independent, in one aspect, said fields may be selected from the group consisting of
      (1) an electric field;
      (2) a magnetic field;
      (3) an electromagnetic field;
      (4) a vibrational field, in one aspect a sonic field;
      (5) a flow field;
      (6) a shear field
      (7) an accelerational field, in one aspect a gravitational and/or centrifugal field;
      (8) the status of the product and/or system's boundary with respect to the exchange of mass and/or free energy with said product and/or system's environment; in one aspect, said environment may comprise a plurality of sub-environments wherein at least two sub-environments may comprise different levels of mass and/or energy; in one aspect said exchange of mass may comprise the exchange of a fluid and/or a solid, in one aspect, said fluid and or solid may comprise water and/or a non-aqueous fluid; in one aspect, said the exchange of energy may comprise the exchange heat energy, momentum and/or light energy;
b) said product and/or system's internal state may be altered by:
   i) a change in said internal state's energy level, in one aspect said energy may comprise
      (1) heat
      (2) electromagnetic radiation, in one aspect, said electromagnetic radiation may be in the radiofrequency, microwave frequency, infrared frequency, visible frequency, ultraviolet frequency and/or x-ray frequency range
      (3) electricity
      (4) work, in one aspect said work may be applied by sonic perturbations, pressure, and/or mechanical force; and
      (5) combinations thereof
   ii) a change in said product and/or system's internal state by altering said product and/or system's mass, in one aspect, said change may be achieved via the addition or removal of a chemical reactant, a catalyst, a solvent, a filler and mixtures thereof;
   iii) a change in the order of said product and/or system, in one aspect, said change in order may be achieved by changing the orientation of the product and/or system with respect to some externally applied field or reference frame and/or subjecting the product and/or system to a short-lived change in any of the prevailing conditions
c) the independent variable is selected from time, an independently variable prevailing condition and/or the internal state.
   In any aforementioned aspect of said method:
a) the method may be performed in a fixed magnetic field and the monitoring may be accomplished using NMR; and
b) the initial state of said product and/or system may be established by a fixed waiting time that allows progress towards steady state, terminated by the application of one or more radiofrequency and/or magnetic field gradient pulses; and
c) optionally, the method may comprise applying a magnetic field gradient, a radio frequency pulse and/or continuous radiofrequency radiation to product and/or system during any period comprising progress to steady state and/or during the establishment of the initial state.

In any aforementioned aspect of said method:
a) the method may be performed in a variable magnetic field, in one aspect, said variability may be achieved by changing the applied magnetic field and/or by moving the sample among locations having differing magnetic fields; and
b) for the initial state and each period comprising progress to steady state may comprise setting the magnetic field to a value such that at least one of the values is different from the other values that are set; and
c) optionally, the method may comprise applying a magnetic field gradient, a radio frequency pulse and/or continuous radiofrequency radiation to product and/or system during any period comprising progress to steady state and/or during the establishment of the initial state.

In any aforementioned aspect of said method, said product may be a consumer product.

In any aforementioned aspect of said method, said method may be applied to a consumer product, in one aspect a consumer product under in-use conditions.

In any aforementioned aspect of said method, said method may be applied to a material used to produce a consumer product and said material used to produce a consumer product may be a combination of raw materials that forms an intermediate for a consumer product.

In any aforementioned aspect of said method, said material used to produce a consumer product may be a raw material.

In any aforementioned aspect of said method the use of said information may comprise transforming said information into a set of parameters, using a computer to effect such transformation, said transformation comprising the step of:
a) for a One-Dimensional Case
   i) solving the pair of equations D₀=A^{T}A and D_{N}=A^{T}Z^{N}A for the matrices A and Z, wherein:
      (1) D₀ and D_{N} are two matrices containing said information wherein said information is arranged in the matrices according to the expression D_{N}(i,j)=d_{i+j+N-1}, where i and j are the row and column indices, and the data points dₙ are numbered starting at zero for the first data point used, and arranged systematically according to the magnitude of the independent variable;
      (2) the rows of A are the response curves or can be combined to generate response curves;
      (3) the matrix Z is diagonal and may be complex; or
b) For a Two-Dimensional Case
   i) generating and solving equations involving matrices D_{M,N}=A₂^{T}Z₂^{M}SZ₁^{N}A₁ for A₁, Z₁, A₂, Z₂, and S, wherein
      (1) the matrices D_{M,N} are constructed from the data using the formula D_{M,N}(i,j)=d_{i+M-1, j+N-1}, where i and j are the row and column indices of D_{M,N}, and in the notation d_{r,c} the subscripts r and c refer to the row and column indices of the two-dimensional data array, and index 0 refers to the first data point used in each dimension;
      (2) the rows of A₁ and A₂ represent the (possibly complex) component response curves present in the data, or can be combined to represent the response curves;
      (3) the matrices Z₁ and Z₂ are diagonal and may be complex;
      (4) S is the spectral matrix

In any aforementioned aspect of said method, said information's dimensionality is reduced, using a computer, said reduction being achieved with no respect to a kernel.

In any aforementioned aspect of said method, said information's dimensionality is reduced, using a computer, said reduction comprising by using a set of orthogonal basis functions to achieve such reduction.

A product or system that is designed, made, changed and/or used using the information obtained according to any of the aforementioned aspects of the aforementioned methods is disclosed.

### EXAMPLES

### Example 1

### Simple Kinetic Relaxation Analysis of 2D Dynamic Vapor Sorption

This section gives a worked example of how to develop a theoretical description of a two-dimensional relaxometry experiment applied to a simple system. This illustrates how a relaxation matrix can be derived from a kinetic model, and how this can be used to describe the expected results for a two-dimensional experiment. We consider sorption kinetics of a vapor V on a material having two types of binding sites, a and b, in which bound material V can move among the a and b sites according to a first order process. The kinetic equations are

$$\begin{matrix}a + V {{• }_{{k}_{- a}}}^{{k}_{+ a}} aV & ( 0.35 ) \\ b + V {{•}^{{k}_{+ b}}}_{{k}_{- b}} bV & ( 0.36 ) \\ aV + b {{•}^{{k}_{ab}}}_{{k}_{ba}} + bV & ( 0.37 )\end{matrix}$$

Using the methods of relaxation kinetics, we define parameters αₐ and α_{b} that indicate the distance from equilibrium of reactants a and b, respectively.

[a]=[a]_{eq}+αₐ (0.38)

[b]=[b]_{eq}+α_{b} (0.39)

[V]=[V]_{eq}+αₐ+α_{b} (0.40)

From these expressions and the well-known methods of chemical kinetics, it follows that

$$\frac{d}{d t} {α}_{a} = ( - {{{k}_{+ a} [ a ]}_{eq} [ V ]}_{eq} + {{k}_{- a} [ aV ]}_{eq} ) + ( {{{k}_{ab} [ aV ]}_{eq} [ b ]}_{eq} - {{{k}_{ba} [ a ]}_{eq} [ bV ]}_{eq} ) + {α}_{a} ( - {{k}_{+ a} [ a ]}_{eq} - {{k}_{+ a} [ V ]}_{eq} - {k}_{- a} - {{k}_{ab} [ b ]}_{eq} - {{k}_{ba} [ bV ]}_{eq} ) + {α}_{b} ( - {{k}_{+ a} [ a ]}_{eq} + {{k}_{ab} [ aV ]}_{eq} + {{k}_{ba} [ a ]}_{eq} ) + ( - {k}_{+ a} {α}_{a}^{2} - {k}_{+ a} {α}_{a} {α}_{b} - {k}_{ab} {α}_{a} {α}_{b} + {k}_{ba} {α}_{a} {α}_{b} ) \qquad ( 0.41 )$$

The first line of (0.41) contains only equilibrium concentrations, and is equal to zero. The second line is first order in αₐ, while the third line is first order in α_{b}. For the fourth line, assuming that the distance from equilibrium is small, the second order products of small numbers will render this line is negligible. Neglect of such second-order terms is a common assumption made in the field of relaxation kinetics, and is valid when the system is not too far from equilibrium. A similar expression for

$$\frac{d}{d t} {α}_{b}$$

can be generated in the same way. The overall time dependence of the deviation from equilibrium can then be written as

$$\begin{matrix}\frac{d}{d t} [ \begin{matrix}{α}_{a} \\ {α}_{b}\end{matrix} ] = [ \begin{matrix}{R}_{a , a} & {σ}_{a , b} \\ {σ}_{b , a} & {R}_{b , b}\end{matrix} ] [ \begin{matrix}{α}_{a} \\ {α}_{b}\end{matrix} ] \\ where & ( 0.42 ) \\ {R}_{a , a} = - ( {{k}_{+ a} [ a ]}_{eq} + {{k}_{+ a} [ V ]}_{eq} + {k}_{- a} + {{k}_{ab} [ b ]}_{eq} + {{k}_{ba} [ bV ]}_{eq} ) & ( 0.43 ) \\ {R}_{b , b} = - ( {{k}_{+ b} [ b ]}_{eq} + {{k}_{+ b} [ V ]}_{eq} + {k}_{- b} + {{k}_{ba} [ a ]}_{eq} + {{k}_{ab} [ aV ]}_{eq} ) & ( 0.44 ) \\ {σ}_{a , b} = ( - {{k}_{+ a} [ a ]}_{eq} + {{k}_{ab} [ aV ]}_{eq} + {{k}_{ba} [ a ]}_{eq} ) & ( 0.45 ) \\ {σ}_{b , a} = ( - {{k}_{+ b} [ b ]}_{eq} + {{k}_{ab} [ bV ]}_{eq} + {{k}_{ab} [ b ]}_{eq} ) & ( 0.46 )\end{matrix}$$

Because the equilibrium distribution of site occupancy will change if V is added or removed or other prevailing conditions are changed, the relaxation matrix itself will also change because the equilibrium concentrations depend on these prevailing conditions. Even if the exchange reaction shown in equation (0.37) does not occur (0=k_{ab}=k_{ba}), the off-diagonal relaxation elements σ_{a,b} and σ_{b,a} will still be non-zero and unequal (except possibly by accident). The physical origin of this “cross talk” is that depletion of V due to binding to one type of site (say a) influences its availability to bind to the other kind of site (say b).

Following the more efficient symbol conventions defined above, we will express (0.42) as

$$\begin{matrix}\frac{d}{d t} m = Rm \\ where & ( 0.47 ) \\ m = [ \begin{matrix}{α}_{a} \\ {α}_{b}\end{matrix} ] \\ and & ( 0.48 ) \\ R = [ \begin{matrix}{R}_{a , a} & {σ}_{a , b} \\ {σ}_{ b , a} & {R}_{b , b}\end{matrix} ] & ( 0.49 )\end{matrix}$$

The next step of the analysis is to examine how the deviations from equilibrium are related to the measured signal in a two-dimensional experiment. As an example of a simple and low-resolution measurement tool, we will assume that the signal is monitored gravimetrically. The difference in the mass of the sample from the equilibrium mass is proportional to αₐ+α_{b}.

The state vector at the end of period E will be

m(t_{E})=e^{R}^{_{E}}^{t}^{_{E}}m₀ (0.50)

The switch in prevailing conditions (concentration of V) from periods E to D will change the state vector to

m(t_{E},t_{D}=0)=e^{R}^{_{E}}^{t}^{_{E}}m₀+δ (0.51)

where δ gives the change in equilibrium positions characterizing periods E and D. Then, following the evolution time, the relaxation state vector will be

m(t_{E},t_{D})=e^{R}^{_{D}}^{t}^{_{D}}e^{R}^{_{E}}^{t}^{_{E}}m₀+e^{R}^{_{D}}^{t}^{_{D}}δ (0.52)

Continuing to follow the procedure outlined in the theory section, the signal during the detection period will be

d(t_{E},t_{D})=1^{T}e^{R}^{_{D}}^{t}^{_{D}}e^{R}^{_{E}}^{t}^{_{E}}m₀+1^{T}e^{R}^{_{D}}^{t}^{_{D}}δ (0.53)

and expanding the exponentials for easier analysis gives

d(t_{E},t_{D})=(1^{T}V_{D})e^{Λ}^{_{D}}^{t}^{_{D}}(V_{D}⁻¹V_{E})e^{Λ}^{_{E}}^{t}^{_{E}}(V_{E}⁻¹m₀)+(1^{T}V_{D})e^{Λ}^{_{D}}^{t}^{_{D}}(V_{D}⁻¹δ) (0.54)

For regularly sampled data, this would be

d_{j,k}=\tilde{1}^{T}Z_{D}^{j}\tilde{V}_{M}Z_{E}^{k}\tilde{m}₀+\tilde{1}^{T}Z_{D}^{j}\tilde{δ} (0.55)

For processing, we wish to represent the results in a form such as equation (0.20) or equation (0.24), so we must consider the consequences of having the t_{E}-independent second term (the axial term) in equation (0.55). Depending on the motivations of the measurement, it may or may not be desirable to preserve the information contained in this “axial” term. If no special precautions are taken, and if linear self modeling of the form of equation (0.24) is desired, this axial term will contribute a row of ones to the matrix A_{E}, the corresponding element of Z_{E} will also be one, and the elements of S that interact with this component will map the elements of δ. It will sometimes be desirable and/or possible to suppress the axial contribution experimentally. For example, an experiment that reproduces the behavior of this term (possibly by using a very long duration of period E, followed by a normal measurement) can be subtracted from the data set. Alternatively, if it is possible to shift the prevailing conditions so that the value of δ changes sign from scan-to-scan, then addition of scans so executed can eliminate this term. Other methods reminiscent of phase cycling in NMR can be envisioned.

### Example 2

### Two-Dimensional Dynamic Vapor Sorption

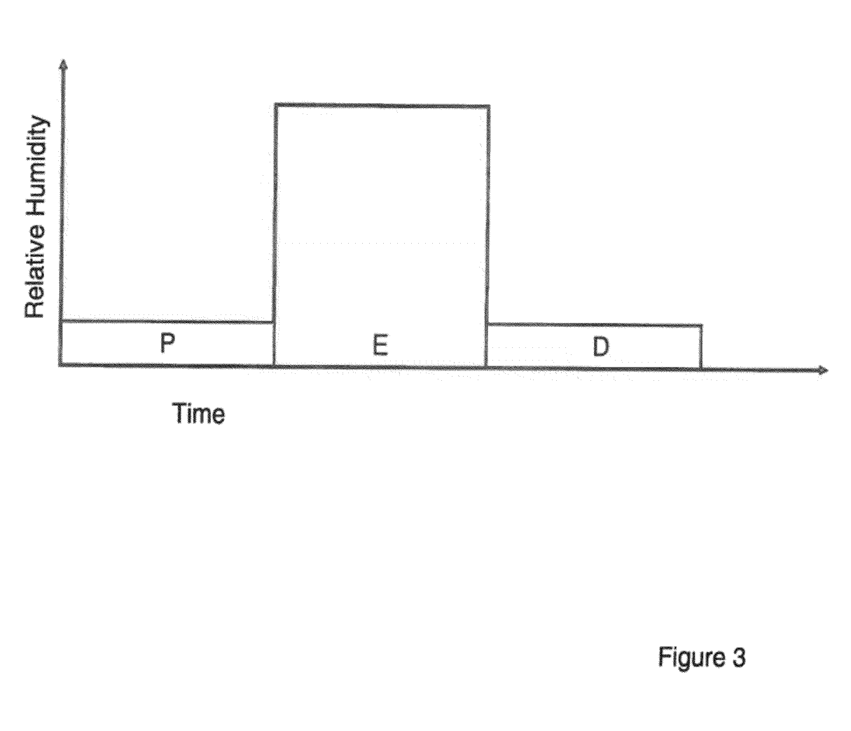

FIG. 3 shows the experiment design used to acquire two-dimensional dynamic vapor sorption data. Period P is a preparation period in which the relative humidity is set and maintained at a low value for a time sufficient to achieve an internal state very close to equilibrium. Period D is an evolution period. The relative humidity is switched to a high value. On each repetition of the protocol, the duration of this period is incremented to achieve adequate sampling of the hydration phase of the kinetic scheme. Period D is a detection period. The relative humidity is set to a low value during this period. On each repetition of the protocol, the mass of the sample is monitored as it approaches the equilibrium value appropriate to the prevailing conditions during period D. Note that the state of the system at the outset of period D will depend on the duration of period E, so that each repetition of the protocol will sample a different starting configuration and will therefore show different behavior. For the experiment described in FIG. 3, the signal is defined as the mass of the sample, possibly corrected for a reference state such as the mass of the dry sample, and the signal sources can be viewed as the types of physical locations at which water vapor adsorbs, desorbs, migrates, condenses, etc.

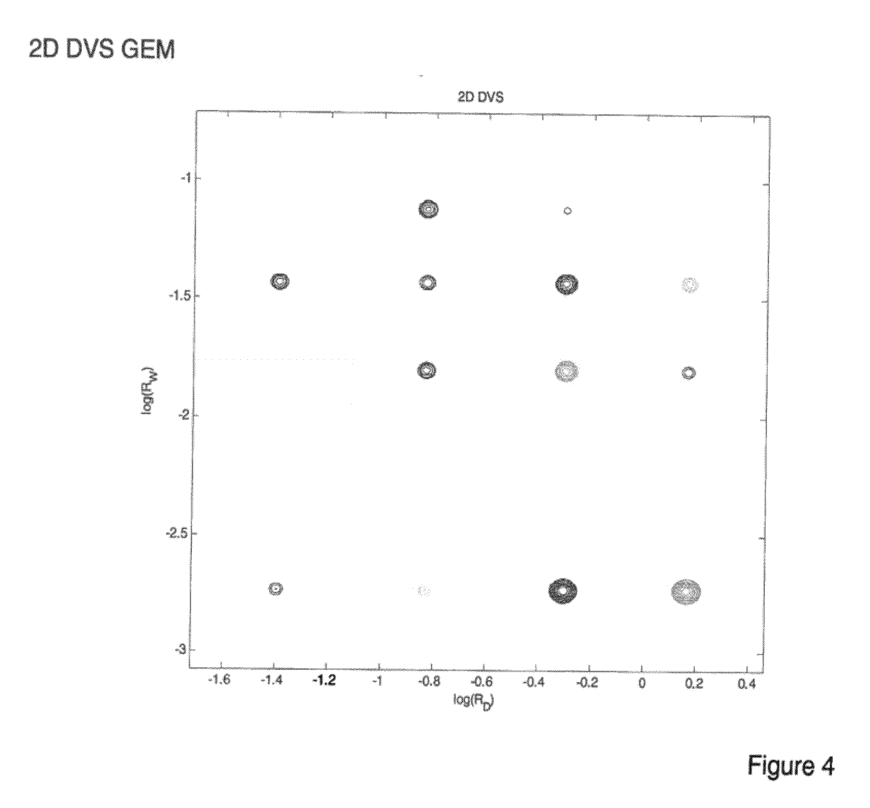

FIG. 4 displays the results of linear self-modeling of the data in the form of a contour plot. In constructing FIG. 4, each signal was converted to a Gaussian signal having a height proportional to the signal height, and given an arbitrary width to enable visualization. Contour lines are spaced at exponentially increasing heights at increments of \sqrt{2}. Positive peaks are shown in black, negative peaks in red. As will be shown below, the use of a contour plot facilitates visual interpretation of the results, especially comparison of results on related samples. This presentation does not show the axial peaks that result from the experiment. Another representation of the same analysis is given in the following table:

| | Wetting Rates | | | |
|---|---|---|---|---|
| Drying rates | 0.039686 | 0.14625 | 0.48994 | 1.4449 |
| −4.0908e−005 | 0.41063 | 0.76714 | 1.7882 | −1.3598 |
| 0.0018408 | −0.1162 | 0.11438 | −1.233 | 1.1695 |
| 0.015823 | −0.038245 | −0.20205 | 0.40461 | −0.10805 |
| 0.036555 | −0.19766 | −0.15993 | −0.40022 | 0.14106 |
| 0.075738 | 0.0040971 | −0.2589 | −0.069692 | 0.056603 |

Note that the first row has a wetting rate relatively close to zero. This row corresponds to the axial signals that arise because of the shift in equilibrium that occurs upon transition from period E to D.

### Example 3

### Applications of 2D NMR Relaxometry

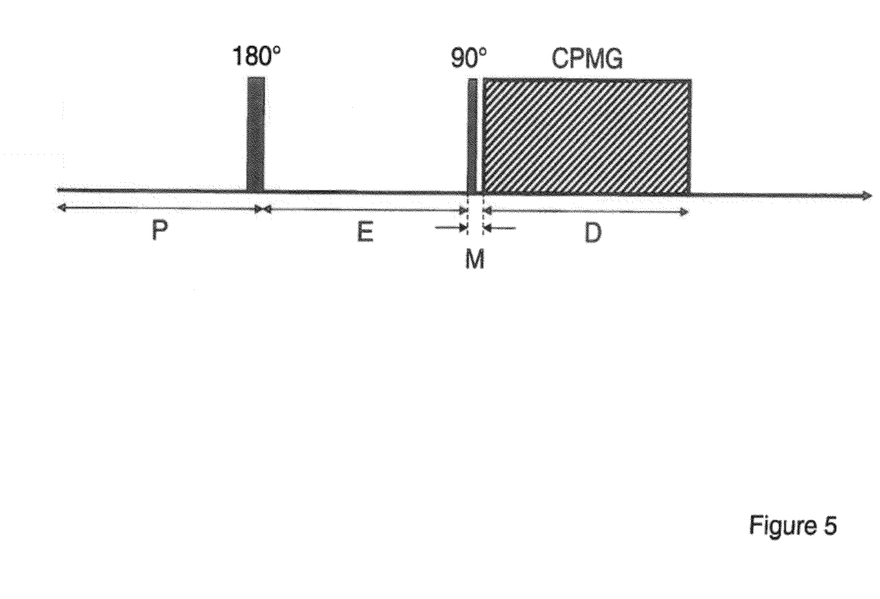

FIG. 5 shows the pulse sequence used for acquiring NMR T₁-T₂ data and used in several subsequent figures. This pulse sequence is well known in the literature, and was among the first two-dimensional relaxometry experiments ever performed. Period P is a preparation period. In this case, the purpose is to reproducibly create a large amount of non-equilibrium transverse magnetization. This is achieved by first allowing the spin systems to relax towards their equilibrium population distributions, and by terminating period P with a “180 degree pulse” which has the effect of inverting the spin populations, creating a non-equilibrium population distribution having an excess of spins in the higher energy spin state. During period E, the signal sources relax towards their equilibrium magnetization to an extent determined by the kinetic relaxation mechanisms and by the duration of Period E. Period M is a mixing period, the purpose of which is to convert the non-equilibrium populations, which correspond to a net magnetization oriented parallel or anti-parallel to the Z axis, into magnetization in the XY plane. The amount of magnetization actually created in the XY plane during period M depends on the state of the system at the end of Period E. Period D is a detection period. It is a measurement of the amount of magnetization in the XY plane acquired while the well-known CPMG (Carr-Purcell-Meiboom-Gill) pulse sequence is being applied. The magnetization is measured at the echo points of the CPMG sequence. The CPMG sequence is designed to monitor the relaxation of the XY magnetization components.

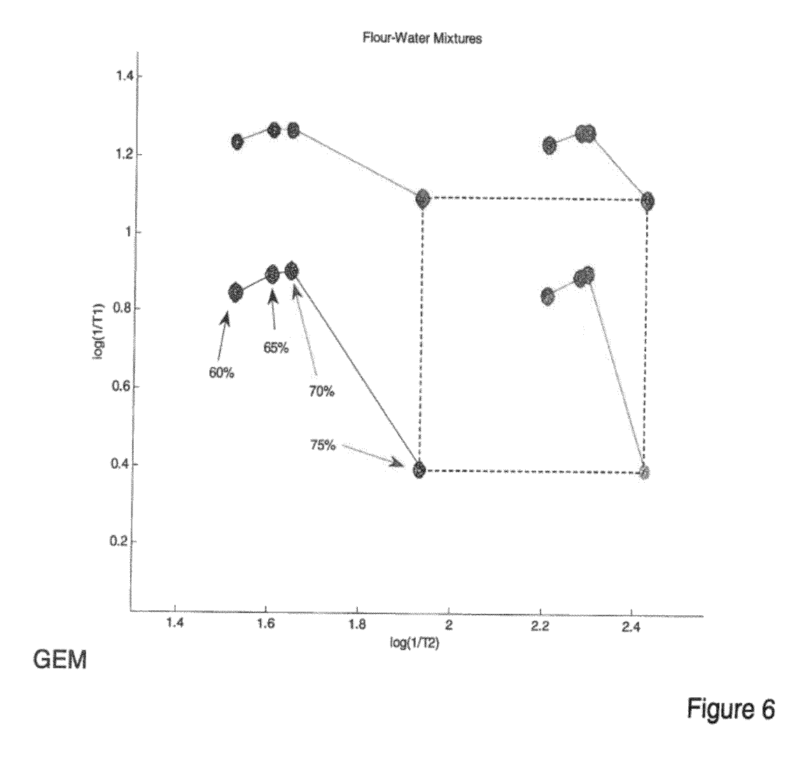

FIG. 6 shows the results of linear self-modeling applied to several different mixtures of flour and water, aged for four hours, and then subjected to the experiment described in FIG. 5. The contour plot was constructed as described above for FIG. 4. Two non-axial relaxation rates were detected in each dimension, and as shown by the dotted rectangle which links the signals for one of the samples, these two relaxation rates create four different elements in the S matrix, visualized as four different cross peaks in the contour plot representation. Each of these signals varies systematically as a function of the weight fraction of flour in the mixtures. There is a large jump in the positions, and a large change in intensities (note the change from positive to negative in the lower right hand signal), as the amount of hydration changes. This abrupt change corresponds to an abrupt change in the tactile properties of the material, going from a “bread dough” consistency to a “pie crust” consistency. Hence, the relaxometry experiment coupled with the linear self-modeling analysis correlates strongly with an important consumer-relevant property.

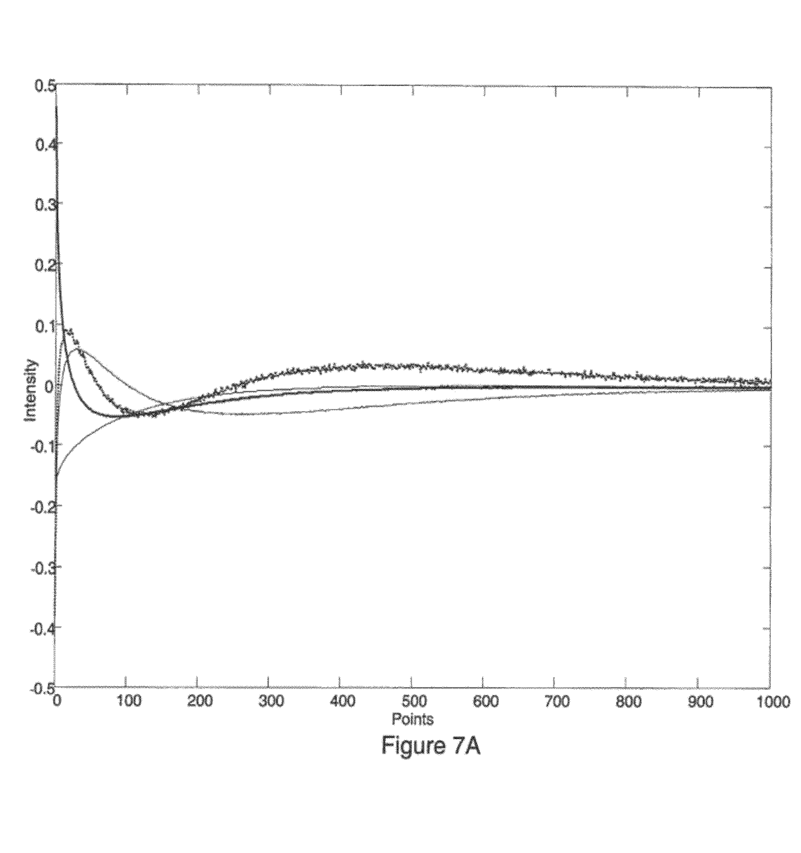

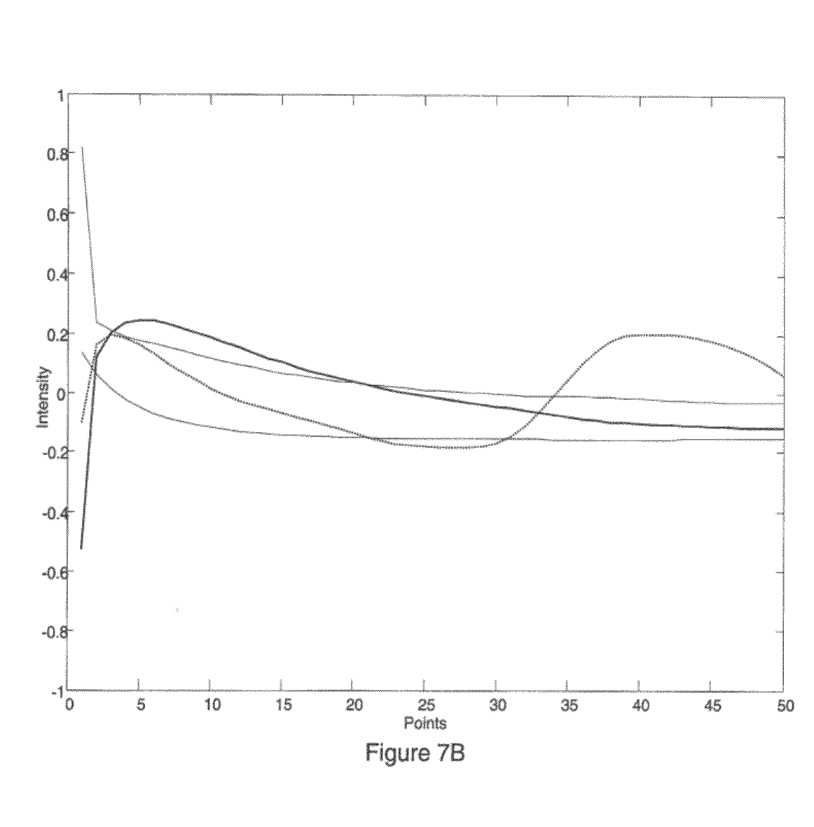

To illustrate the use of Group Self-Modeling, FIG. 7 shows several orthonormal basis curves for the horizontal (top) and vertical (bottom) dimensions extracted from NMR data acquired from 140 examples using the pulse sequence shown in FIG. 5. The sample set for this experiment consisted of 20 samples that were sampled at 7 time points each. The samples were laundry detergent formulations very similar to a market formulation. We find that further analysis of the coefficients of the orthonormal basis curves for each sample using multivariate statistics is closely correlated with the phase structure and long-term phase behavior of the materials.

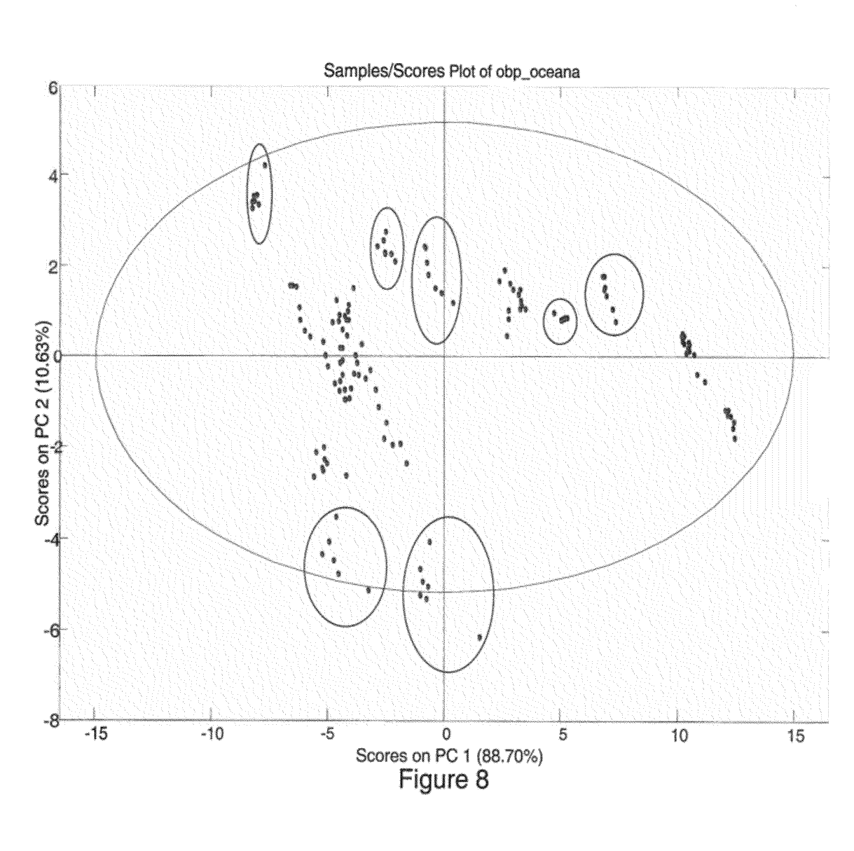

FIG. 8 shows a scores plot from principal components analysis of the parameters generated by Orthogonal Basis Parameterization of the same data described above for FIG. 7. For several of the samples, ellipses are drawn around points that originate from individual samples to emphasize that many of the samples reside in unique regions of the principal components space, and evolve within those unique regions as a function of time. Even though principal components analysis is an unsupervised statistical method, similar samples (with respect to phase structure) reside in similar regions of the scores plot. Supervised multivariate methods can be used to rapidly classify the samples.

What is claimed is:

1) A method of designing, making, changing and/or using a product and/or system comprising:
a) extracting information by
i) establishing the initial state of a product and/or system, said initial state being a non-equilibrium, non-steady state;
ii) allowing the product and/or system to progress towards a steady state, versus an independent variable;
iii) optionally, introducing a period wherein said progress towards said steady state is altered by establishing a discontinuity in the prevailing conditions and/or internal state of said product and/or system without losing the desired information about the state of the product and/or system when said discontinuity is established;
iv) introducing a period wherein said progress towards said steady state is altered by establishing a discontinuity in the prevailing conditions and/or internal state of said product and/or system without losing the desired information about the state of the product and/or system when said discontinuity is established and monitoring said product and/or system's progress towards steady-state using a device that provides the results in a machine readable form, in one aspect, said device comprises a computer,
v) repeating (i)-(iv) one or more times while altering the value of said independent variable.
b) using said information to design, make, change and/or use a product and/or system, in one aspect, said use comprises using a computer to further transform said information into a form that can be more efficiently used.

2) A method according to claim 1 wherein at least one of said steady states is an equilibrium state.

3) A method according to claim 1 comprising one or more additional sets of steps ii) and iii) said additional set of steps ii) and iii) occurring after the initial set of steps ii) and iii); wherein each additional set of steps ii) and iii) has a different independent variable, prevailing conditions and/or internal state from the immediately preceding set of steps ii) and iii).

4) A method according to claim 1 wherein:
a) the method is performed using an analytical or physical measurement tool capable of recording progress towards steady state; and/or
b) the method is performed virtually by means of a computer simulation and progress towards steady state is a calculated function of the computed results.

5) The method of claim 4 wherein progress towards steady state is monitored using an NMR and/or the steady is an equilibrium state that comprises controlled temperature and relative humidity, and progress towards steady state is monitored using gravimetry.

6) A method according to claim 1 wherein
a) the prevailing conditions of said product and/or system are defined by controlling or setting:
i) a thermodynamic and/or structural parameter, in one aspect, said thermodynamic and/or structural parameter may be selected from:
(1) temperature
(2) pressure
(3) volume and/or
(4) container shape
ii) the applied fields and/or the spatial distribution of said fields, said fields being either time dependent or time independent, in one aspect, said fields may be selected from the group consisting of
(1) an electric field;
(2) a magnetic field;
(3) an electromagnetic field;
(4) a vibrational field, in one aspect a sonic field;
(5) a flow field;
(6) a shear field
(7) an accelerational field, in one aspect a gravitational and/or centrifugal field;
(8) the status of the product and/or system's boundary with respect to the exchange of mass and/or free energy with said product and/or system's environment; in one aspect, said environment comprises a plurality of sub-environments wherein at least two sub-environments comprise different levels of mass and/or energy; in one aspect said exchange of mass comprises the exchange of a fluid and/or a solid, in one aspect, said fluid and or solid comprises water and/or a non-aqueous fluid; in one aspect, said the exchange of energy comprises the exchange heat energy, momentum and/or light energy;
b) said product and/or system's internal state is altered by:
i) a change in said internal state's energy level, in one aspect said energy may comprise
(1) heat
(2) electromagnetic radiation, in one aspect, said electromagnetic radiation may be in the radiofrequency, microwave frequency, infrared frequency, visible frequency, ultraviolet frequency and/or x-ray frequency range
(3) electricity
(4) work, in one aspect said work may be applied by sonic perturbations, pressure, and/or mechanical force; and
(5) combinations thereof
ii) a change in said product and/or system's internal state by altering said product and/or system's mass, in one aspect, said change is achieved via the addition or removal of a chemical reactant, a catalyst, a solvent, a filler and mixtures thereof;
iii) a change in the order of said product and/or system, in one aspect, said change in order may be achieved by changing the orientation of the product and/or system with respect to some externally applied field or reference frame and/or subjecting the product and/or system to a short-lived change in any of the prevailing conditions
c) the independent variable is selected from time, an independently variable prevailing condition and/or the internal state.

7) A method according to claim 1 wherein
a) the method is performed in a fixed magnetic field and the monitoring is accomplished using NMR; and
b) the initial state of said product and/or system is established by a fixed waiting time that allows progress towards steady state, terminated by the application of one or more radiofrequency and/or magnetic field gradient pulses; and
c) optionally, the method comprises applying a magnetic field gradient, a radio frequency pulse and/or continuous radiofrequency radiation to product and/or system during any period comprising progress to steady state and/or during the establishment of the initial state.

8) A method according to claim 1 wherein:
a) the method is performed in a variable magnetic field, in one aspect, said variability is achieved by changing the applied magnetic field and/or by moving the sample among locations having differing magnetic fields; and
b) for the initial state and each period comprising progress to steady state comprises setting the magnetic field to a value such that at least one of the values is different from the other values that are set; and
c) optionally, the method comprises applying a magnetic field gradient, a radio frequency pulse and/or continuous radiofrequency radiation to product and/or system during any period comprising progress to steady state and/or during the establishment of the initial state.

9) A method according to claim 1 wherein said product is a consumer product.

10) A method according to claim 1, wherein said method is applied to a consumer product, in one aspect a consumer product under in-use conditions and/or a material used to produce a consumer product.

11) The method of claim 10 wherein said material used to produce a consumer product is a combination of raw materials that forms an intermediate for a consumer product.

12) The method of claim 10 wherein said material used to produce a consumer product is a raw material.

13) The method of claim 1 wherein the use of said information comprises transforming said information into a set of parameters, using a computer to effect such transformation, said transformation comprising the step of:
a) For a One-Dimensional Case
i) solving the pair of equations D₀=A^{T}A and D_{N}=A^{T}Z^{N}A for the matrices A and Z, wherein:
(1) D₀ and D_{N} are two matrices containing said information wherein said information is arranged in the matrices according to the expression D_{N}(i,j)=d_{i+j+N-1}, where i and j are the row and column indices, and the data points dₙ are numbered starting at zero for the first data point used, and arranged systematically according to the magnitude of the independent variable;
(2) the rows of A are the response curves or can be combined to generate response curves;
(3) the matrix Z is diagonal and may be complex; or
b) For a Two-Dimensional Case
i) generating and solving equations involving matrices D_{M,N}=A₂^{T}Z₂^{M}SZ₁^{N}A₁ for A₁, Z₁, A₂, Z₂, and S, wherein
(1) the matrices D_{M,N} are constructed from the data using the formula D_{M,N}(i,j)=d_{i+M-1, j+N-1}, where i and j are the row and column indices of D_{M,N}, and in the notation d_{r,c} the subscripts r and c refer to the row and column indices of the two-dimensional data array, and index 0 refers to the first data point used in each dimension;
(2) the rows of A₁ and A₂ represent the (possibly complex) component response curves present in the data, or can be combined to represent the response curves;
(3) The matrices Z₁ and Z₂ are diagonal and may be complex;
(4) S is the spectral matrix

14) The method of claim 1 wherein said information's dimensionality is reduced, using a computer, said reduction being achieved with no respect to a kernel.

15) The method of claim 1 wherein said information's dimensionality is reduced, using a computer, said reduction comprising by using a set of orthogonal basis functions to achieve such reduction.

16) A product or system that is designed, made, changed and/or used using the information obtained according to claims 1.
